(19) United States
(12) Patent Application Publication
(10) Pub. No.: US 2021/0310347 A1
(43) Pub. Date: Oct. 7, 2021

(54) METHOD FOR GEOLOGICAL STEERING CONTROL THROUGH REINFORCEMENT LEARNING

(71) Applicant: SHELL OIL COMPANY, HOUSTON, TX (US)

(72) Inventors: Neilkunal PANCHAL, Houston, TX (US); Sami Mohammed Khair SULTAN, Houston, TX (US); Minith Bharat JAIN, Maharashtra (IN); Patricia ASTRID, Houston, TX (US)

(21) Appl. No.: 17/263,986

(22) PCT Filed: Jul. 30, 2019
(86) PCT No.: PCT/US2019/044036

§ 371 Date: Jan. 28, 2021

Related U.S. Application Data
(60) Provisional application No. 62/712,506, filed on Jul. 31, 2018.

(51) Int. Cl. E21B 44/00; E21B 7/04; G06F 30/27; G06N 3/08

(52) U.S. Cl. CPC E21B 44/00; E21B 7/04; E21B 2200/22; G06N 3/08; E21B 2200/20; G06F 30/27

(57) ABSTRACT

A method for autonomous geosteering for a well-boring process uses a trained function approximating agent. A geological objective is determined. Then, using the trained function approximating agent, a sequence of control inputs is determined to steer a well-boring tool towards the geological objective. The trained function approximating agent is adapted to enact the sequence of control inputs upon receiving a signal from a measurement from the well-boring process.

### FIELD OF THE INVENTION

The present invention relates to the field of geosteering and, in particular, to a method for autonomous geosteering for a well-boring process.

### BACKGROUND OF THE INVENTION

In a well construction process, rock destruction is guided by a drilling assembly. The drilling assembly includes sensors and actuators for biasing the trajectory and determining the heading in addition to properties of the surrounding borehole media. The intentional guiding of a trajectory to remain within the same rock or fluid and/or along a fluid boundary such as an oil/water contact or an oil/gas contact is known as geosteering.

Geosteering is drilling a horizontal wellbore that ideally is located within or near preferred rock layers. As interpretive analysis is performed while or after drilling, geosteering determines and communicates a wellbore's stratigraphic depth location in part by estimating local geometric bedding structure. Modern geosteering normally incorporates more dimensions of information, including insight from downhole data and quantitative correlation methods. Ultimately, geosteering provides explicit approximation of the location of nearby geologic beds in relationship to a wellbore and coordinate system.

Geosteering relies on mapping data acquired in the structural domain along the horizontal wellbore and into the stratigraphic depth domain Relative Stratigraphic Depth (RSD) means that the depth in question is oriented in the stratigraphic depth direction and is relative to a geologic marker. Such a marker is typically chosen from type log data to be the top of the pay zone/target layer. The actual drilling target or “sweet spot” is located at an onset stratigraphic distance from the top of the pay zone/target layer.

U.S. Pat. No. 8,892,407B2 (ExxonMobil) relates to a process for well trajectory planning. The process involves receiving data relevant to drilling and completion of an oil or gas well, and to reservoir development. Well trajectory and drilling and completion decision parameters are simultaneously calculated using a Markov decision process-based model that accounts for an uncertain parameter to optimize an objective function that generates a plan for drilling and completion of one or more oil or gas wells. The objective function optimizes one or more performance metrics that include reservoir performance, well drilling performance, and financial performance, subject to satisfying constraints on the drilling.

There is a need for autonomous geosteering that is trained by a function approximating agent.

### SUMMARY OF THE INVENTION

According to one aspect of the present invention, there is provided a method for autonomous geosteering for a well-boring process, comprising the steps of: (a) providing a trained function approximating agent; (b) determining a geological objective; (c) determining a sequence of control inputs to steer a well-boring tool towards the geological objective, wherein the trained function approximating agent is adapted to enact the sequence of control inputs upon receiving a signal from a measurement from the well-boring process.

### BRIEF DESCRIPTION OF THE DRAWINGS

The method of the present invention will be better understood by referring to the following detailed description of preferred embodiments and the drawings referenced therein, in which:

FIG. 1 illustrates a result of one embodiment of the present invention;

FIG. 2 illustrates one embodiment of a reward function suitable for the method of the present invention;

FIG. 3 is a graphical representation of the results of a first test of a simulation environment produced according to the method of the present invention;

FIG. 4 is a graphical representation of the results of a second test of a simulation environment produced according to the method of the present invention;

FIG. 5 is a graphical representation of the results of a third test of a simulation environment produced according to the method of the present invention; and

FIG. 6 is a graphical representation of the results of a fourth test of a simulation environment produced according to the method of the present invention.

### DETAILED DESCRIPTION OF THE INVENTION

The present invention provides a method for autonomous geosteering using a trained function approximating agent. The method is a computer-implemented method.

By “function approximating agent” we mean a process for finding an underlying relationship from a given finite set of input-output data. Examples of function approximating agents include neural networks, such as backpropagation-enabled processes, including deep learning, machine learning, frequency neural networks, Bayesian neural networks, Gaussian processes, polynomials, and derivative-free processes, such as annealing processes, evolutionary processes and sampling processes.

Preferably, the function approximating agent is trained on a physical simulator approximating a real geological and drilling operation, for example, in the intended subterranean formation.

Preferably, the function approximating agent is trained according to the method described in co-pending application entitled “Method for Simulating a Coupled Geological and Drilling Environment” filed in the USPTO on the same day as the present application, as provisional application U.S. 62/712,490 filed 31 Jul. 2018, the entirety of which is incorporated by reference herein.

In a preferred embodiment, the function approximating agent may be trained by (a) providing an earth model defining boundaries between formation layers and petrophysical properties of the formation layers in a subterranean formation comprising data selected from the group consisting of seismic data, data from an offset well and combinations thereof, and producing a set of model coefficients; (b) providing a toolface input corresponding to the set of model coefficients to a drilling attitude model for determining a drilling attitude state; (c) determining a drill bit position in the subterranean formation from the drilling attitude state; (d) feeding the drill bit position to the training earth model, and determining an updated set of model coefficients for a predetermined interval and a set of signals representing physical properties of the subterranean formation for the drill bit position; (e) inputting the set of signals to a sensor model for producing at least one sensor output and determining a sensor reward from the at least one sensor output; (f) correlating the toolface input and the corresponding drilling attitude state, drill bit position, set of model coefficients, and the at least one sensor output and sensor reward in the simulation environment; and (g) repeating steps b)-f) using the updated set of model coefficients from step d).

The drilling model for the simulation environment may be a kinematic model, a dynamical system model, a finite element model, a Markov decision process, and combinations thereof.

Preferred examples of function approximating agents include stochastic clustering and pattern matching, greedy Monte Carlo, differential dynamic programming, and combinations and derivatives thereof.

Preferably, the function approximating agent is trained by reinforcement learning, deep reinforcement learning, approximate dynamic programming, stochastic optimal control, and combinations thereof.

According to the method of the present invention, a sequence of control inputs is determined to steer a well-boring tool towards a geological objective. The geological objective may, for example, without limitation, a relative 1D position, a relative 2D position, a relative 3D position, a dip angle, a strike angle, and combinations thereof. The sequence of control inputs includes, without limitation, curvature, roll angle, set points for inclination, set points for azimuth, Euler angle, rotation matrix quaternions, angle axis, position vector, position Cartesian, polar, and combinations thereof

The trained function approximating agent is adapted to enact the sequence of control inputs upon receiving a signal from a measurement from the well-boring process.

Preferably, a reward function is used in the method of the present invention. More preferably, the reward function is based on a reward objective including, without limitation, shortest distance to the geological objective, lowest percentage of out-of-zone time, lowest deviation from targeted relative stratigraphic depth, lowest deviation from a well plan, reaching a target waypoint, consistency with target heading, lowest number of steering correction control signals, minimizing angular deviation, and combinations thereof. More preferably, the reward function further includes, without limitation, negative rewards for reduced drilling speed, increased wear on drill bit, proximity to region identified as being nearby a well, proximity to region having a geological feature that should be avoided, and combinations thereof. Preferably, the reward function includes negative rewards for angular deviation, tortuosity, excess curvature, and combinations thereof.

Examples of a geological objective include an existing well, a target well path for a future well, simulations of an existing well, simulations of a target well path for a future well, and combinations thereof. Often, a target well path avoids collision with an existing well. However, there are times when collision with an existing well is the objective, for example, without limitation, when the objective is a relief well. In this case, the reward function has a positive reward for colliding with the geological objective.

In another embodiment, the reward function includes a positive episodic reward for an episodic action including, without limitation, reaching a predetermined end depth, reaching a target zone, extending a predetermined number of feet in a target zone, and combinations thereof. The reward function may also include a negative reward for an episodic action including, without limitation, missing the target, deviating too far from a predetermined geological datum, entering into a no-go zone, and combinations thereof. Examples of a no-go zone include, without limitation, lease lines, permeability, porosity, petrophysical properties, nearby wells, and the like. Examples of a geological datum can be, for example, without limitation, a rock formation boundary, a geological feature, an offset well, an oil/water contact, an oil/gas contact, an oil/tar contact and combinations thereof.

The output action can be an action including, without limitation, curvature, roll angle, set points for inclination, set points for azimuth, Euler angle, rotation matrix quaternions, angle axis, position vector, position Cartesian, polar, and combinations thereof.

In a preferred embodiment, the well-boring process is modeled as a Markov decision process.

Preferably, the trained function approximating agent is solved by Model Predictive Control, which reframes the task of following a trajectory as an optimization problem. The solution to the optimization problem is the optimal trajectory. Model Predictive Control involves simulating different actuator inputs, predicting the resulting trajectory and selecting that trajectory with a minimum cost. Parameters involved are starting state, process model, reference trajectory, errors, length, duration, cost function and constraints.

Two embodiments are illustrated below:

$${θ}_{t + 1} = {θ}_{t} + rop * a 1 * dt$$

$${φ}_{t + 1} = {φ}_{t} + rop * \frac{a 2}{sin ( {θ}_{t} )} * dt$$

$${North}_{t + 1} = {North}_{t} + rop * sin ( {θ}_{t + 1} ) * cos ( {φ}_{t + 1} ) * dt$$

$${East}_{t + 1} = {East}_{t} + rop * sin ( {θ}_{t + 1} ) * sin ( {φ}_{t + 1} ) * dt$$

$${TVD}_{t + 1} = {TVD}_{t} + rop * cos ( {θ}_{t + 1} ) * dt$$

$${rop}_{t + 1} = {rop}_{t} + a * dt$$

$$Where , \text{\textbar}$$

$$a 1 = dls * cos ( tf )$$

$$a 2 = dls * sin ( tf )$$

$${θ}_{t + 1} = {θ}_{t} + rop * dls * cos ( tf ) * dt$$

$${φ}_{t + 1} = {φ}_{t} + rop * dls * \frac{sin ( tf )}{sin ( {θ}_{t} )} * dt$$

$${North}_{t + 1} = {North}_{t} + rop * sin ( {θ}_{t + 1} ) * cos ( {φ}_{t + 1} ) * dt$$

$${East}_{t + 1} = {East}_{t} + rop * sin ( {θ}_{t + 1} ) * sin ( {φ}_{t + 1} ) * dt$$

$${TVD}_{t + 1} = {TVD}_{t} + rop * cos ( {θ}_{t + 1} ) * dt$$

$${rop}_{t + 1} = {rop}_{t} + a * dt$$

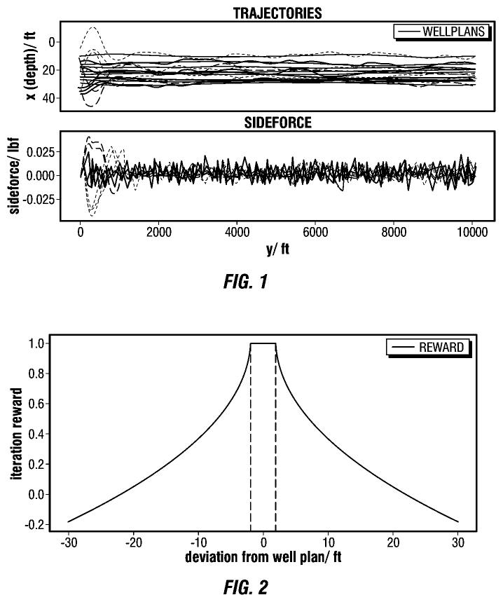

Referring now to FIG. 1, the accuracy of the method the present invention is illustrated by the solid trajectory lines and their proximation to the dashed well plan lines. The deviation from the well plans at the beginning of the tests is caused in large measure by controls to avoid curvature angles that are unrealistic for a drilling assembly. As shown in FIG. 1, the sideforce is curvature.

FIG. 2 illustrates one embodiment of a reward function. The vertical dashed lines represent a user-defined tolerance. The shape of the curve can also be selected by the user, depending on the user's objective. As shown in FIG. 2, the reward function is selected to balance precision and speed, in this case with a coasting threshold of 0.60 m (2 ft) and a coasting bonus of 0.3. The coasting threshold is the distance from the well plan at which the user wants the bottom hole assembly to prioritize speed over accuracy.

### EXAMPLES 1-4

The accuracy of the simulation environment produced in accordance with the present invention was tested by training a function approximating agent.

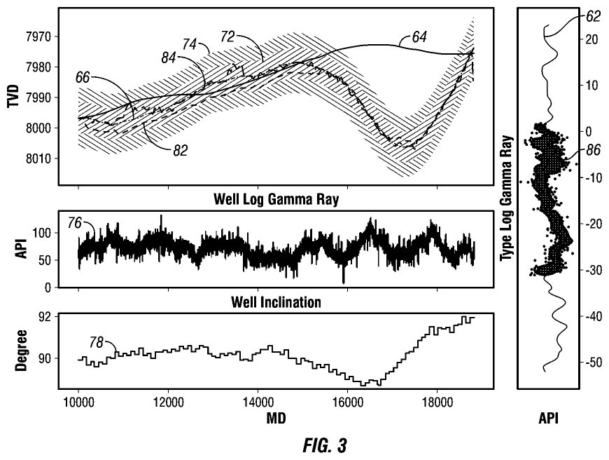

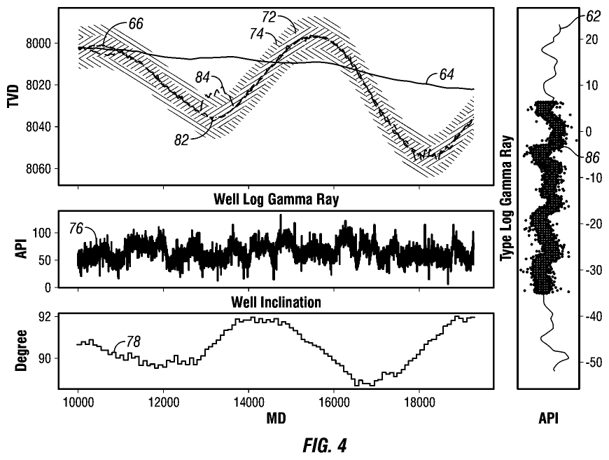

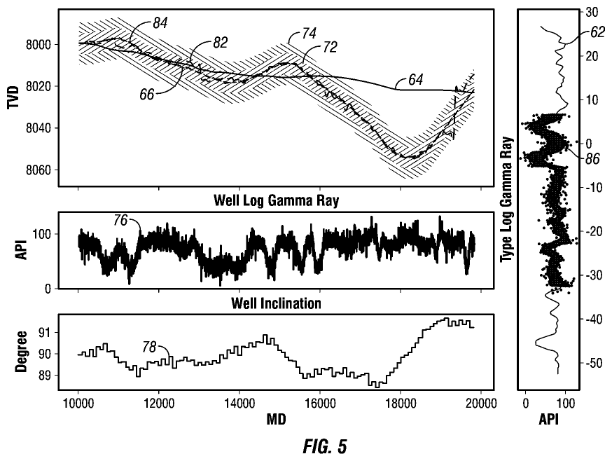

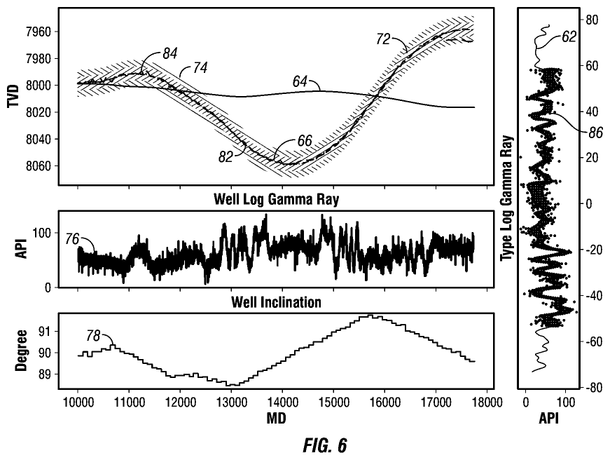

Referring now to FIGS. 3-6, a synthetic well was generated based on an actual gamma ray log. The real data is identified by a type log gamma ray plot 62. Based on the type log gamma ray plot 62, a boundary 64 representing the top of a target formation was determined and a synthetic true well path 66 was generated. Region 72 represents a 1.5-m (5-foot) error about the true well path 66, while region 74 represents a 3-m (10-foot) error about the well path 66. The goal of the test was to match the true well path 66 as best as possible.

In each of Example 1-4, the function approximating agent is described in co-pending application entitled “Process for Real Time Geological Localization with Bayesian Reinforcement Learning” filed in the USPTO on the same day as the present application, as provisional application U.S. 62/712,518 filed 31 Jul. 2018, the entirety of which is incorporated by reference herein. The Bayesian Reinforcement Learning (BRL) function approximating agent was trained according to the method described in co-pending application entitled “Method for Simulating a Coupled Geological and Drilling Environment” filed in the USPTO on the same day as the present application, as provisional application U.S. 62/712,490 filed 31 Jul. 2018, the entirety of which is incorporated by reference herein.

Well log gamma ray data 76 was fed to the trained agent and a set of control inputs, in this case well inclination angle 78, was used to steer the well-boring along the true well path 66, according to the method described herein.

The well path 82 resulting from the BRL agent and the well path 84 resulting from the BRL agent with mean square error demonstrated good fit to the true well path 66. As shown in FIGS. 3-6, the fit of well paths 82 and 84 improved over time with a reward function described in the autonomous geosteering method.

While preferred embodiments of the present disclosure have been described, it should be understood that various changes, adaptations and modifications can be made therein without departing from the spirit of the invention(s) as claimed below.

1. A method for autonomous geosteering for a well-boring process, comprising the steps of:
a) providing a trained function approximating agent;
b) determining a geological objective;
c) determining a sequence of control inputs to steer a well-boring tool towards the geological objective,
wherein the trained function approximating agent is adapted to enact the sequence of control inputs upon receiving a signal from a measurement from the well-boring process.

2. The method of claim 1, further comprising the step of providing a reward function.

3. The method of claim 2, wherein the reward function is based on a reward objective selected from the group consisting of shortest distance to the geological objective, lowest percentage of out-of-zone time, lowest deviation from targeted relative stratigraphic depth, lowest deviation from a well plan, reaching a target waypoint, consistency with target heading, lowest number of steering correction control signals, minimizing angular deviation and combinations thereof.

4. The method of claim 3, wherein the reward function comprises negative rewards for reduced drilling speed, increased wear on drill bit, proximity to region identified as being nearby a well, proximity to region having a geological feature that should be avoided, and combinations thereof.

5. The method of claim 2, wherein the reward function comprises negative rewards for angular deviation, tortuosity, excess curvature, and combinations thereof.

6. The method of claim 2, wherein the reward function comprises a positive episodic reward for an episodic action selected from the group consisting of reaching a predetermined end depth, reaching a target zone, extending a predetermined number of feet in a target zone, and combinations thereof.

7. The method of claim 2, wherein the reward function comprises a negative episodic reward for an episodic action selected from the group consisting of missing the target, deviating too far from a predetermined geological datum, entering into a no-go zone, and combinations thereof.

8. The method of claim 2, wherein the geological objective is selected from the group consisting of an existing well, a target well path for a future well, simulations of an existing well, simulations of a target well path for a future well, and combinations thereof, and wherein the reward function comprises a positive reward for colliding with the geological objective.

9. The method of claim 1, wherein the function approximating agent is trained by a function approximating process selected from the group consisting of reinforcement learning, deep reinforcement learning, approximate dynamic programming, stochastic optimal control, and combinations thereof.

10. The method of claim 1, wherein the well-boring process is modelled as a Markov decision process.

11. The method of claim 1, wherein the trained function approximating agent is solved by Model Predictive Control with respect to a simulation environment or a state space model.

12. The method of claim 1, wherein the sequence of control inputs is selected from the group consisting of curvature, roll angle, set points for inclination, set points for azimuth, Euler angle, rotation matrix quaternions, angle axis, position vector, position Cartesian, polar, and combinations thereof.

13. The method of claim 1, wherein the geological objective is selected from the group consisting of a relative 1D position, a relative 2D position, a relative 3D position, a dip angle, a strike angle, and combinations thereof.

14. The method of claim 1, wherein the function approximating agent is trained in a simulation environment.

15. The method of claim 14, wherein the simulation environment approximates a real geological and drilling operation.

16. The method of claim 14, wherein the simulation environment is produced by a training method comprising the steps of:
a) providing an earth model defining boundaries between formation layers and petrophysical properties of the formation layers in a subterranean formation comprising data selected from the group consisting of seismic data, data from an offset well and combinations thereof, and producing a set of model coefficients;
b) providing a toolface input corresponding to the set of model coefficients to a drilling attitude model for determining a drilling attitude state;
c) determining a drill bit position in the subterranean formation from the drilling attitude state;
d) feeding the drill bit position to the earth model, and determining an updated set of model coefficients for a predetermined interval and a set of signals representing physical properties of the subterranean formation for the drill bit position;
e) inputting the set of signals to a sensor model for producing at least one sensor output and determining a sensor reward from the at least one sensor output;
f) correlating the toolface input and the corresponding drilling attitude state, drill bit position, set of model coefficients, and the at least one sensor output and sensor reward in the simulation environment; and
g) repeating steps b)-f) using the updated set of model coefficients from step d).
